(19) United States
(12) Patent Application Publication
(10) Pub. No.: US 2010/0181598 A1
(43) Pub. Date: Jul. 22, 2010

(54) SEMICONDUCTOR DEVICE AND METHOD OF MANUFACTURING SEMICONDUCER DEVICE

(76) Inventors: Tsutomu SATO, Oita (JP); Jun Idebuchi, Oita (JP); Yoshihisa Arie, Oita (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/648,974

(22) Filed: Dec. 29, 2009

(30) Foreign Application Priority Data
Jan. 21, 2009 (JP) 2009-011282

(51) Int. Cl. H01L 29/78; H01L 21/336

(52) U.S. Cl. 257/190; 438/285; 257/E21.431; 257/E29.255

(57) ABSTRACT

Etch block layers having an etching rate smaller than that of a first semiconductor forming a semiconductor substrate are formed on the sidewalls of device isolation grooves by applying oblique ion implantation of Ox, N, or C to the semiconductor substrate including the first semiconductor. Embedded layers including a second semiconductor are selectively formed in recesses by epitaxial-growing the second semiconductor having a lattice constant larger than that of the first semiconductor in the recesses.

### CROSS-REFERENCE TO RELATED APPLICATIONS

This application is based upon and claims the benefit of priority from the prior Japanese Patent Application No. 2009-011282, filed on Jan. 21, 2009; the entire contents of which are incorporated herein by reference.

### BACKGROUND OF THE INVENTION

1. Field of the Invention

The present invention relates to a semiconductor device and a method of manufacturing the semiconductor device, more particularly is suitably applied to a method of embedding a SiGe layer in a source region and a drain region of a field effect transistor.

2. Description of the Related Art

In a high-speed logic device and the like, to realize an increase in speed of a field effect transistor, a method of embedding a SiGe layer in a source region and a drain region to apply compression stress to a channel region and increase mobility of holes may be adopted (Japanese Patent Application Laid-Open No. 2008-147597).

However, when the SiGe layer is selectively embedded and grown in the source region and the drain region, the SiGe layer is thin at a device isolation end because the SiGe layer is not formed. Therefore, sufficient compression stress cannot be applied to the channel region and the performance of the field effect transistor falls.

### BRIEF SUMMARY OF THE INVENTION

A method of manufacturing a semiconductor device according to an embodiment of the present invention comprises: arranging a first mask member on a semiconductor substrate including a first semiconductor; forming openings in the first mask member; forming device isolation grooves in the semiconductor substrate by etching the semiconductor substrate using the first mask member, in which the openings are formed, as a mask; forming etch block layers having an etching rate smaller than that of the first semiconductor on sidewalls and bottoms of the device isolation grooves by applying oblique ion implantation of Ox, N, or C to the semiconductor substrate using the first mask member as a mask; forming device isolation insulating layers in the device isolation grooves, on the sidewalls of which the etch block layers are formed; forming a gate electrode on the semiconductor substrate, which is device-isolated by the device isolation insulating layers, via a gate insulating film; forming recesses separated from the device isolation insulating layers on both sides of the gate electrode by etching the semiconductor substrate on both the sides of the gate electrode to leave the etch block layers at ends of the device isolation insulating layers; and embedding and growing embedded layers including a second semiconductor having a lattice constant larger than that of the first semiconductor in the recesses.

A method of manufacturing a semiconductor device according to an embodiment of the present invention comprises: forming device isolation insulating layers in a semiconductor substrate including a first semiconductor; forming a gate electrode on the semiconductor substrate, which is device-isolated by the device isolation insulating layer, via a gate insulating film; forming a resist pattern in which openings are formed on both sides of the gate electrode, the resist pattern being arranged to extend from ends of the device isolation insulating layers in directions of the gate electrode; forming recesses separated from the device isolation insulating layers in a source region and a drain region on both the sides of the gate electrode by etching the semiconductor substrate using the resist pattern as mask; and embedding and growing embedded layers including a second semiconductor having a lattice constant larger than that of the first semiconductor in the recesses.

A semiconductor device according to an embodiment of the present invention comprises: a semiconductor substrate including a first semiconductor; a gate electrode formed on the semiconductor substrate via a gate insulating film; embedded layers embedded in a source region and a drain region on both sides of the gate electrode and including a second semiconductor having a lattice constant larger than that of the first semiconductor; and etch block layers arranged between the embedded layers and device isolation ends and formed with an impurity contained in the first semiconductor to have an etching rate smaller than that of the first semiconductor.

### BRIEF DESCRIPTION OF THE DRAWINGS

FIGS. 1A to 1D are sectional views for explaining a method of manufacturing a semiconductor device according to a first embodiment of the present invention;

FIGS. 2A to 2D are sectional views for explaining the method of manufacturing a semiconductor device according to the first embodiment; and

FIGS. 3A to 3D are sectional views for explaining a method of manufacturing a semiconductor device according to a second embodiment of the present invention.

### DETAILED DESCRIPTION OF THE INVENTION

Exemplary embodiments of the present invention are explained in detail below with reference to the accompanying drawings. The present invention is not limited by the embodiments.

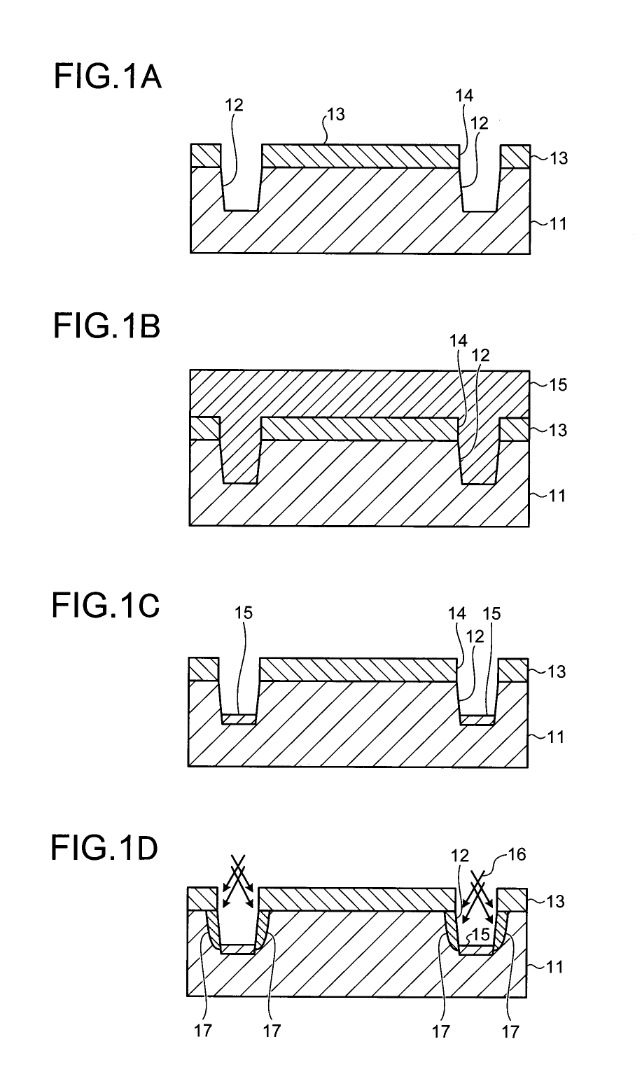

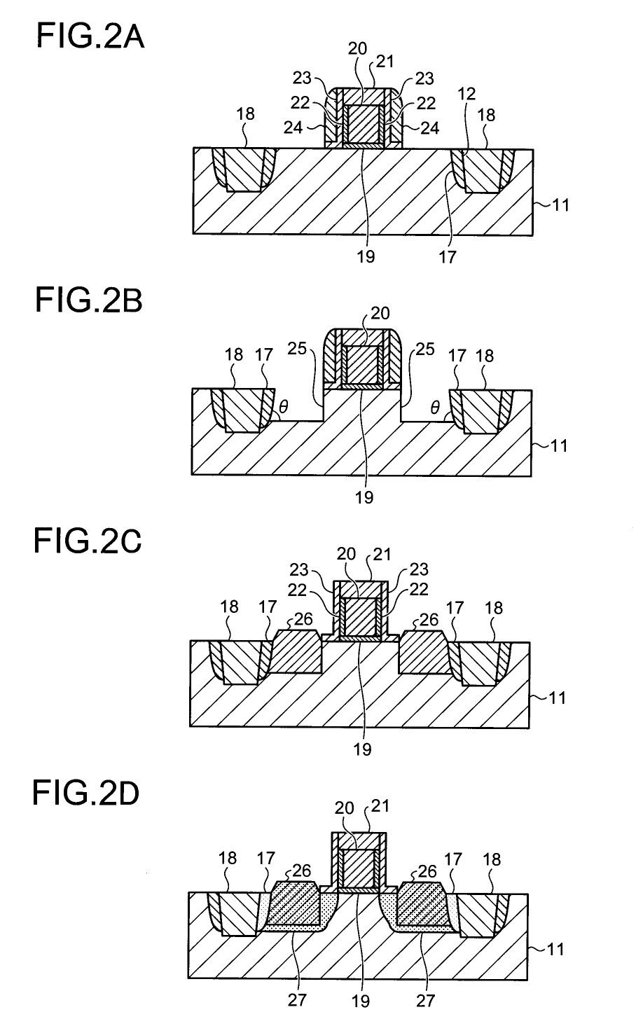

FIGS. 1A to 1D and FIGS. 2A to 2D are sectional views of the schematic configuration of a semiconductor device according to a first embodiment of the present invention.

In FIG. 1A, a mask member 13 is formed on a semiconductor substrate 11 including a first semiconductor by using a method such as the CVD. As a material of the mask member 13, for example, a silicon oxide film or a silicon nitride film can be used. Openings 14 arranged to correspond to device isolation regions on the semiconductor substrate 11 are formed in the mask member 13 by using the photolithography technology and the dry etching technology.

Device isolation grooves 12 are formed in the semiconductor substrate 11 by performing dry etching of the semiconductor substrate 11 using the mask member 13, in which the openings 14 are formed, as a mask.

Subsequently, as shown in FIG. 1B, a mask member 15 is formed on the mask member 13 to fill the device isolation grooves 12. As a material of the mask member 15, for example, a silicon oxide film or a silicon nitride film can be used. A material having an etching rate larger than that of the mask member 13 is desirably selected as the material. When the mask member 15 is formed on the mask member 13, the surface of the mask member 15 is desirably planarized. When a resist is used as the material of the mask member 15, the surface of the mask member 15 can be planarized by applying the mask member 15 over the mask member 13. When the silicon oxide film or the silicon nitride film is used as the material of the mask member 15, if recesses corresponding to the device isolation grooves 12 occur on the surface of the mask member 15, the surface of the mask member can be planarized by a method such as the CMP.

As shown in FIG. 1C, the mask member 15 formed on the mask member 13 is etched back to expose the sidewalls of the device isolation grooves 12 with the bottoms of the device isolation grooves 12 covered with the mask member 15.

As shown in FIG. 1D, etch block layers 17 having an etching rate smaller than that of the first semiconductor forming the semiconductor substrate 11 are formed on the sidewalls of the device isolation grooves 12 by applying oblique ion implantation 16 of Ox, N, or C to the semiconductor substrate 11 using the mask member 13 and the mask member 15 as masks. The concentration of Ox, N, or C introduced into the etching block layers 17 is desirably equal to or higher than 5×10¹⁷ cm⁻³. For example, the concentration of Ox can be set to 5×10¹⁸ cm⁻³. The etch block layers 17 can be formed not only on the sidewalls of the device isolation grooves 12 but also on the bottoms of the device isolation grooves 12 by applying the oblique ion implantation 16 of Ox, N, or C to the semiconductor substrate 11 without forming the mask member 15 on the bottoms of the deice isolation grooves 12.

As shown in FIG. 2A, after the mask member 15 is removed, a device isolation region is formed in the semiconductor substrate 11 by embedding device isolation insulating layers 18 in the device isolation grooves 12, on the sidewalls of which the etching block layers 17 are provided. As a material of the device isolation insulating layers 18, for example, a silicon oxide film can be used. After the mask member 13 is removed, a gate electrode 20 with a cap insulating layer 21 on top of it is formed on the semiconductor substrate 11, via a gate insulating film 19. As a material of the gate insulating film 19, for example, a silicon oxide film can be used or a high-dielectric insulating film such as an Hf oxide can be used. As the gate electrode 20, for example, a polysilicon gate can be used or a silicide or metal gate can be used.

Oxide layers 22 are formed on the sidewalls of the gate electrode 20 by performing thermal oxidation of the gate electrode 20. Sidewall insulating layers 23 and 24 are formed on the sidewalls of the gate electrode 20. A material of the cap insulating layer 21 and the sidewall insulating layer 23 desirably has resistance against diluted fluoric acid. For example, a silicon nitride film can be used as the material. As a material of the sidewall insulating layer 24, for example, a silicon oxide film can be used.

As shown in FIG. 2B, recesses 25 arranged on both the sides of the gate electrode 20 are formed in the semiconductor substrate 11 by performing dry etching of the semiconductor substrate 11 using the gate electrode 20, on which the sidewall insulating layers 24 are formed, as a mask. The etch block layers 17 having an etching rate smaller than that of the semiconductor substrate 11 are already formed on the sidewalls of the device isolation insulating layers 18. Therefore, the recesses 25 formed in the semiconductor substrate 11 are separated from the device isolation insulating layers 18 via the etching block layers 17 by etching the semiconductor substrate 11 to leave the etch block layers 17 at ends of the device isolation insulating layers 18.

A taper angle θ of the recesses 25 can be controlled by adjusting an etching condition for dry-etching the semiconductor substrate 11. The shape of the recesses 25 can be adjusted to be suitable for embedding and growing layers. For example, when a mixed gas containing HBr/CF₄/O₂/He is used as an etching gas during the dry etching of the semiconductor substrate 11, the taper angle θ of the recesses 25 can be increased by increasing a flow rate of O₂.

The recesses 25 can be formed in the semiconductor substrate 11 in a self-aligning manner by using the etch block layers 17, the device isolation insulating layers 18, the cap insulating layer 21, and the sidewall insulating layers 23 and 24 as etch stop films.

As shown in FIG. 2C, native oxide films on the surfaces of the recesses 25 are removed by performing diluted fluoric acid treatment of the semiconductor substrate 11 in which the recesses 25 are formed. When the sidewall insulating layers 24 include a silicon oxide film, the sidewall insulating layers 24 are also removed when the diluted fluoric acid treatment is performed.

Embedded layers 26 including a second semiconductor are selectively formed in the recesses 25 by epitaxial-growing the second semiconductor in the recesses 25. The embedded layers 26 are desirably projected to a position higher than the surfaces of the device isolation insulating layers 18. The second semiconductor forming the embedded layers 26 can be selected to have a lattice constant larger than that of the first semiconductor. As materials of the first semiconductor and the second semiconductor, a combination selected out of Si, Ge, SiGe, SiC, SiSn, PbS, GaAs, GaAlAs, InP, GaInAsP, GaP, GaN, ZnSe, and the like can be used. In particular, when the first semiconductor is Si, SiGe is desirably used as the second semiconductor layer. This makes it possible to set the lattice constant of the second semiconductor larger than that of the first semiconductor while making it possible to realize lattice alignment between the first semiconductor and the second semiconductor.

When SiGe is formed in the recesses 25 as the embedded layers 26, film formation temperature is set in a range of 700° C. to 750° C. As a material gas, a mixed gas containing SiH₄ (and/or SiH₂Cl₂)/GeH₄/HCl/(and B₂H₆) can be used.

Before the second semiconductor is epitaxial-grown in the recesses 25, the native oxide films on the surfaces of the recesses 25 are desirably removed by performing thermal treatment of the semiconductor substrate 11 in a hydrogen atmosphere. As conditions for the thermal treatment, the purity of hydrogen is desirably set to 100%, temperature is desirably set to be equal to or higher than 820° C., and pressure is desirably set to be equal to or higher than 150 Torr. For example, the temperature can be set to 830° C., the pressure can be set to 150 Torr, and processing time can be set to 1 minute.

Because the etch block layers 17 are formed at the ends of the device isolation insulating layers 18, the embedded layers 26 can be embedded in the recesses 25 without being set in contact with the device isolation insulating layers 18. Therefore, the thickness of the embedded layers 26 can be secured over the entire surfaces of the embedded layers 26 and sufficient compression stress can be applied to a channel region under the gate electrode 20. This makes it possible to increase mobility of holes in the channel region and realize an increase in speed of a P-channel field effect transistor.

Migration of the first semiconductor forming the semiconductor substrate 11 can be suppressed by introducing an impurity such as Ox, N, or C into the semiconductor substrate 11. Therefore, even when the thermal treatment of the semiconductor substrate 11 is performed, the etch block layers 17 at the ends of the device isolation insulating layers 18 can be suppressed from collapsing. This makes it possible to hold the etch block layers 17 at the ends of the device isolation insulating layers 18.

As shown in FIG. 2D, impurity introducing layers 27 are formed on both the sides of the gate electrode 20 by injecting an impurity such as B or BF₂ into a source region and a drain region in which the embedded layers 26 are embedded. The impurity introducing layers 27 can be formed to extend to the outer side of the embedding layers 26 or can be formed on the inner side of the embedded layer 26.

The embedded layers 26 have an effect in increasing the mobility of the holes. Therefore, the embedded layers 26 are provided only in the P-channel field effect transistor. In the case of an N-channel field effect transistor, the same effect can be obtained by using, as the second semiconductor, a material having a lattice constant smaller than that of the first semiconductor.

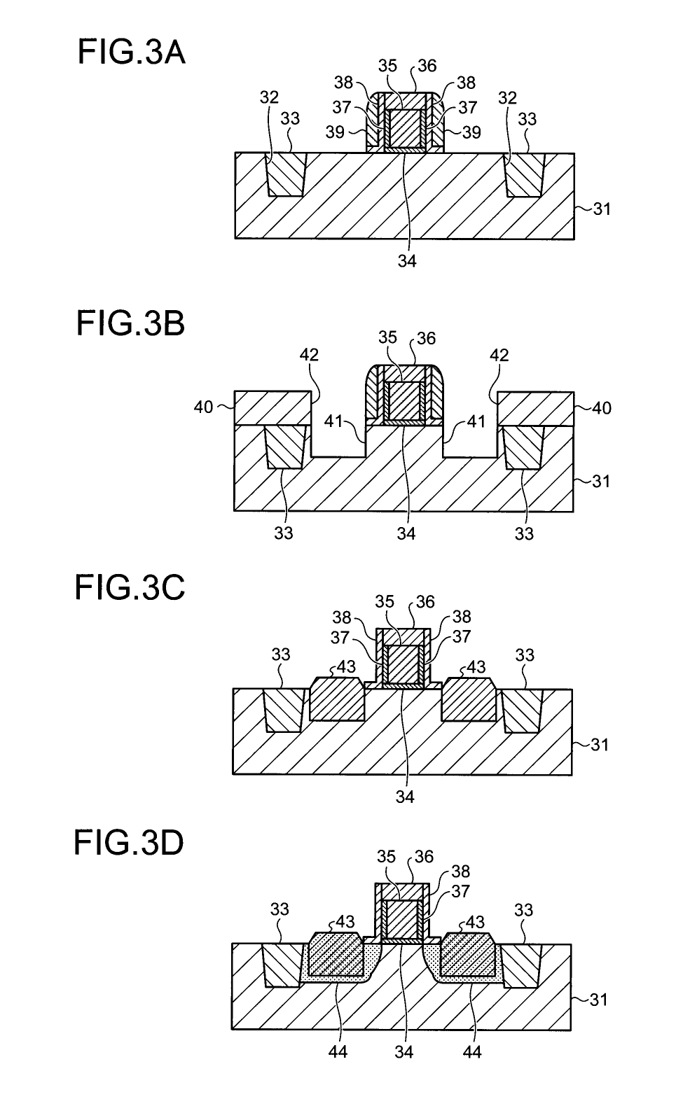

FIG. 3 is a sectional view of the schematic configuration of a semiconductor device according to a second embodiment of the present invention.

In FIG. 3A, device isolation grooves 32 are formed in a semiconductor substrate 31 including a first semiconductor. Device isolation regions are formed in the semiconductor substrate 31 by embedding device isolation insulating layers 33 in the device isolation grooves 32.

A gate electrode 35 with a cap insulating layer 36 on top of it is formed on the semiconductor substrate 31, via a gate insulating film 34.

Oxide layers 37 are formed on the sidewalls of the gate electrode 35 by performing thermal oxidation of the gate electrode 35. Sidewall insulating layers 38 and 39 are formed on the sidewalls of the gate electrode 35.

Subsequently, as shown in FIG. 3B, resist patterns 40, in which openings 42 are formed on a source region and a drain region on both the sides of the gate electrode 35, are formed on the semiconductor substrate 31 by using the photolithography technology. The resist patterns 40 can be arranged to extend from ends of the device isolation insulating 33 in the directions of the gate electrode 35.

Recesses 41 arranged on both the sides of the gate electrode 35 to be separated from the device isolation insulating layers 33 are formed in the semiconductor substrate 31 by performing dry etching of the semiconductor substrate 31 using the resist patterns 40 and the gate electrode 35 as masks.

As shown in FIG. 3C, after the resist patterns 40 are removed, native oxide films on the surfaces of the recesses 41 are removed by performing diluted fluoric acid treatment of the semiconductor substrate 31 in which the recesses 41 are formed.

Embedded layers 43 including a second semiconductor are selectively formed in the recesses 41 by epitaxial-growing the second semiconductor in the recesses 41. The embedded layers 43 are desirably projected to a position higher than the surfaces of the device isolation insulating layers 33. The second semiconductor forming the embedded layers 43 can be selected to have a lattice constant larger than that of the first semiconductor. In particular, when the first semiconductor is Si, SiGe is desirably used as the second semiconductor layer.

Before the second semiconductor is epitaxial-grown in the recesses 41, the native oxide films on the surfaces of the recesses 41 are desirably removed by performing thermal treatment of the semiconductor substrate 31 in a hydrogen atmosphere.

As shown in FIG. 3D, impurity introducing layers 44 are formed on both the sides of the gate electrode 35 by injecting an impurity such as B or BF₂ into the source region and the drain region in which the embedded layers 43 are embedded.

Consequently, the embedded layers 43 can be embedded in the recesses 41 without being set in contact with the device isolation insulating layers 33 and the thickness of the embedded layers 43 can be secured over the entire surfaces of the embedded layers 43. Therefore, sufficient compression stress can be applied to a channel region under the gate electrode 35. This makes it possible to increase mobility of holes in the channel region and, therefore, realize an increase in speed of a P-channel field effect transistor.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device comprising:
arranging a first mask member on a semiconductor substrate including a first semiconductor;
forming openings in the first mask member;
forming device isolation grooves in the semiconductor substrate by etching the semiconductor substrate using the first mask member, in which the openings are formed, as a mask;
forming etch block layers having an etching rate smaller than that of the first semiconductor on sidewalls and bottoms of the device isolation grooves by applying oblique ion implantation of Ox, N, or C to the semiconductor substrate using the first mask member as a mask;
forming device isolation insulating layers in the device isolation grooves, on the sidewalls of which the etch block layers are formed;
forming a gate electrode with a cap insulating layer on the semiconductor substrate, via a gate insulating film;
forming recesses separated from the device isolation insulating layers on both sides of the gate electrode by etching the semiconductor substrate on both the sides of the gate electrode to leave the etch block layers at ends of the device isolation insulating layers; and
embedding and growing embedded layers including a second semiconductor having a lattice constant larger than that of the first semiconductor in the recesses.

2. The method of manufacturing a semiconductor device according to claim 1, further comprising arranging a second mask member on the bottoms of the device isolation grooves, wherein
the etch block layers having an etching rate smaller than that of the first semiconductor are formed on the sidewalls of the device isolation grooves by applying the oblique ion implantation of Ox, N, or C to the semiconductor substrate using the first mask member and the second mask member as masks.

3. The method of manufacturing a semiconductor device according to claim 1, wherein concentration of Ox, N, or C is equal to or higher than 5×10¹⁷ cm⁻³.

4. The method of manufacturing a semiconductor device according to claim 1, wherein the first semiconductor is Si and the second semiconductor is SiGe.

5. The method of manufacturing a semiconductor device according to claim 1, further comprising:
forming sidewall insulating layers on sidewalls of the gate electrode, wherein
the recesses are formed on both sides of the gate electrode in a self-aligning manner by etching the semiconductor substrate on both the sides of the gate electrode using the etch block layers, the device isolation insulating layers, the cap insulating layer, and the sidewall insulating layers as etch stop films.

6. The method of manufacturing a semiconductor device according to claim 1, further comprising performing thermal treatment of the semiconductor substrate having the recesses under conditions that purity of hydrogen is 100%, temperature is equal to or higher than 820° C., and pressure is equal to or higher than 150 Torr before embedding and growing the embedded layers in the recesses.

7. The method of manufacturing a semiconductor device according to claim 1, wherein compression stress is applied to a channel region between the embedded layers.

8. The method of manufacturing a semiconductor device according to claim 1, wherein the embedded layers are projected to a position higher than surfaces of the device isolation insulating layers.

9. A method of manufacturing a semiconductor device comprising:
forming device isolation insulating layers in a semiconductor substrate including a first semiconductor;
forming a gate electrode with a cap insulating layer on the semiconductor substrate, via a gate insulating film;
forming a resist pattern in which openings are formed on both sides of the gate electrode, the resist pattern being arranged to extend from ends of the device isolation insulating layers in directions of the gate electrode;
forming recesses separated from the device isolation insulating layers in a source region and a drain region on both the sides of the gate electrode by etching the semiconductor substrate using the resist pattern as a mask; and
embedding and growing embedded layers including a second semiconductor having a lattice constant larger than that of the first semiconductor in the recesses.

10. The method of manufacturing a semiconductor device according to claim 9, wherein the first semiconductor is Si and the second semiconductor is SiGe.

11. The method of manufacturing a semiconductor device according to claim 9, further comprising performing thermal treatment of the semiconductor substrate having the recesses under conditions that purity of hydrogen is 100%, temperature is equal to or higher than 820° C., and pressure is equal to or higher than 150 Torr before embedding and growing the embedded layers in the recesses.

12. The method of manufacturing a semiconductor device according to claim 9, wherein compression stress is applied to a channel region between the embedded layers.

13. The method of manufacturing a semiconductor device according to claim 9, wherein the embedded layers are projected to a position higher than surfaces of the device isolation insulating layers.

14. A semiconductor device comprising:
a semiconductor substrate including a first semiconductor;
a gate electrode formed on the semiconductor substrate via a gate insulating film;
embedded layers embedded in a source region and a drain region on both sides of the gate electrode and including a second semiconductor having a lattice constant larger than that of the first semiconductor; and
etch block layers arranged between the embedded layers and device isolation ends and formed with an impurity contained in the first semiconductor to have an etching rate smaller than that of the first semiconductor.

15. The semiconductor device according to claim 14, wherein the impurity is Ox, N, or C.

16. The semiconductor device according to claim 15, wherein concentration of Ox, N, or C is equal to or higher than 5×10¹⁷ cm⁻³.

17. The semiconductor device according to claim 14, wherein a taper angle θ is given to boundaries between the embedded layers and the etch block layers.

18. The semiconductor device according to claim 14, wherein the first semiconductor is Si and the second semiconductor is SiGe.

19. The semiconductor device according to claim 14, wherein compression stress is applied to a channel region between the embedded layers.

20. The semiconductor device according to claim 14, wherein the embedded layers are projected to a position higher than surfaces of the device isolation insulating layers.
